(19) United States
(12) Patent Application Publication
(10) Pub. No.: US 2026/0335800 A1
(43) Pub. Date: Oct. 29, 2026

(54) Collection Device Using Fluid Vortex to Increase Collection Efficiency

(71) Applicants: Jong-Soo Shin, Cheongju-si, Chungcheongbuk-do (KR); Shinyang Inc., Cheongju-si, Chungcheongbuk-do (KR)

(72) Inventor: Jong-Soo Shin, Cheongju-si, Chungcheongbuk-do (KR)

(21) Appl. No.: 19/107,209

(22) PCT Filed: Dec. 2, 2022
(86) PCT No.: PCT/KR2022/019461

§ 371 Date: Feb. 27, 2025

(30) Foreign Application Priority Data
Sep. 2, 2022 (KR) 10-2022-0111571

(51) Int. Cl. B01D 45/16; B01D 47/02; B01D 53/18

(52) U.S. Cl. CPC B01D 45/16; B01D 47/022; B01D 53/185; B01D 2257/406; B01D 2257/553; B01D 2258/0216

(57) ABSTRACT

The present invention relates to a collection device using a fluid vortex to increase collection efficiency and, more specifically, to a collection device that maximizes the collection efficiency for a specific material to be collected, by causing a difference in fluid flow rate to occur in the internal space of the housing in which fluid flows, or by creating an additional space in communication with the internal space to facilitate the generation of vortex.

### TECHNICAL FIELD

The present invention relates to a collection device that enhances collection efficiency by utilizing fluid vortex, and more specifically, relates to a collection device that maximizes collection efficiency of specific target substance by promoting generation of vortex through either creating velocity difference in fluid flow within internal space of housing or by establishing additional space communicating with internal space.

### BACKGROUND ART

Semiconductor is generally manufactured through various processes such as oxidation, etching, deposition, photolithography, and others, and such manufacturing process involves use of toxic gases such as ammonia (NH3), nitric oxide (NO), arsine (AsH3), phosphine (PH3), and others.

In case waste gas generated from semiconductor manufacturing process is discharged into atmosphere without treatment, it may cause fatal adverse effect on human body due to aforementioned toxic gas, and fire accident due to spontaneous ignition of waste gas may also occur.

For such reason, in semiconductor manufacturing process, generated waste gas is purified through scrubber and so on and discharged into atmosphere.

Such scrubbers comprise heat-wet scrubber which burns waste gas using induction heating method in indirect combustion wet type and filters once more using water, wet scrubber which collects waste gas using water in wet type and purifies water, and burn-wet scrubber which is direct combustion wet type that burns waste gas with high temperature flame and then collecting using water.

Scrubber uses water in process of treating waste gas regardless of type, and used water contains many contaminants, SO water containing contaminants should be treated with filter and so on and discharged to outside through drain pipe.

At this time, if part of the water used in process of treating waste gas in the scrubber is not discharged through the drain pipe and is discharged to outside along with purified fluid in a liquid or gas state, corrosion-causing liquid component exists in discharged fluid, which may corrode pipe, reduces purification effect of waste gas, and causes fire due to ignition.

Therefore, conventionally, liquid collection device for removing corrosion-causing liquid component from the purified fluid in the scrubber was installed and operated.

FIG. 1 illustrates a conventional liquid collection device 90, which is disclosed in Korean Patent Publication No. 10-2003-0052170 (2003.06.26.).

Referring to FIG. 1, conventional liquid collection device 90 was installed on connection pipe between a scrubber S neutralizing discharged waste gas and an exhaust duct D discharging purified gas through scrubber S.

The liquid collection device 90 consists of a cylindrical upper collection container 91 and a lower collection container 93, and an inlet pipe 911 is installed on one side connected to connection pipe in upper collection container 91, and an exhaust pipe 913 is installed on other side facing the inlet pipe 911 with height difference.

A metal collecting mesh 9131 is formed on inner side of inlet of the exhaust pipe 913, and the lower collection container 93 has an outlet 931 formed at lower end to periodically discharge collected powder and condensed water, and screw-fastened and sealed plug 9311 is configured at lower end of the outlet 931 Additionally, circular fixed plate 915 integrally formed is configured at lower end of the upper collection container 91, and fixed plate 933 of same size as the fixed plate 915 is formed at upper end of the lower collection container 93, so the upper collection container 91 and the lower collection container 93 could be joined and bolted together.

Gas introduced through inlet pipe 911 of the liquid collection device 90 is filtered and collected by the mesh 9131, and some powder falls into lower collection container 93 or adheres inside liquid collection device 90, and not only powder but also condensed water from waste gas accumulates in the lower collection container 93, and powder and condensed water collected in lower collection container 93 were periodically discharged by unscrewing the plug 9311 screw-coupled to the outlet 931.

However, such conventional liquid collection device 90 had a problem of not being able to block flame when unexpected explosion of scrubber S occurred.

Since waste gas handled in scrubber S comprises flammable gas and so on, ignition due to various causes can occur, causing fire accident.

Sprinkler installed on exhaust duct D side can suppress fire to some extent when fire occurs, but pipe connecting scrubber S and exhaust duct D is made of PVC material to prevent internal corrosion, making it vulnerable to fire, so when fire accident occurs, flame easily moves along pipe, easily leading to large-scale fire.

Eventually, when explosion of scrubber S occurs in process of treating waste gas, flame will move along pipe, but aforementioned conventional liquid collection device 90 does not have separate configuration for preventing and blocking fire, so liquid collection device 90 also fails to block flame and burns, resulting in serious property and human damage.

FIG. 2 is a diagram illustrating installation state of conventional liquid collection device 90, and referring to FIG. 2, conventional liquid collection device 90 required fluid to move horizontally from one side to other side to collect liquid, SO vertically connected pipe from scrubber S was connected to horizontal pipe, and this horizontal pipe was connected to liquid collection device 90, then exhausted fluid was drawn out through horizontal pipe and connected again to vertical pipe to send to exhaust duct.

In other words, according to conventional horizontal liquid collection device 90, considerable space and materials were needed to install liquid collection device 90, and after installation, pipe became very complicated, leading to maintenance difficulties, and above all, inside of pipe was easily corroded as corrosion-inducing liquid component contained in fluid adhere inside pipe due to significant load applied within pipe and large pressure drop. Additionally, there was a problem of decreased liquid collection efficiency, making it ineffective to remove corrosion-inducing liquid component contained in fluid.

As a result, related industry is demanding introduction of new technology that can block spread of fire when fire occurs due to scrubber explosion or others, while minimizing space required for installation, preventing waste of materials, facilitating maintenance, preventing corrosion of pipe, and increasing collection efficiency of corrosion-inducing liquid component.

(Patent Literature 1) Korean Patent Publication No. 10-2003-0052170 (2003.06.26)

### DISCLOSURE

### Technical Problem

Accordingly, the present disclosure has been made keeping in mind the above problems occurring in the related art.

An object of the present disclosure is to provide a collection device that maximizes collection efficiency of specific material to be collected by promoting generation of vortex in internal space of housing part where fluid flows.

Another object of the present disclosure is to provide a collection device that promotes generation of vortex by causing velocity difference of fluid by configuring partition part dividing internal space of housing part.

Yet another object of the present disclosure is to provide a collection device that divides one flow path into multiple flow paths with different flow path widths through partition part, causing vortex to occur due to flow velocity difference between flow paths.

Yet another object of the present disclosure is to provide a collection device that generates vortex by partition part, increasing collection efficiency while allowing substance to be discharged smoothly to outside of collection part through discharge part.

Yet another object of the present disclosure is to provide a collection device that forms clockwise vortex from an inner circumferential surface of the side surface of housing part toward center direction of housing part by forming partition part parallel to streamline direction rising toward outlet part from position spaced apart by certain distance from the inner circumferential surface of the side surface of housing part, and forms flow path width formed by the inner circumferential surface of the side surface housing part and partition part relatively narrow to cause fastest flow velocity in corresponding flow path.

Yet another object of the present disclosure is to provide collection device that fluid rapidly rising by partition part meets a first wing part to form vortex by forming the first wing part formed inclined downward on upper side of partition part.

Yet another object of the present disclosure is to provide collection device that maximizes vortex phenomenon caused by fluid with increased flow velocity due to partition part by forming first extension part extended downward from the other end of first wing part.

Yet another object of the present disclosure is to provide collection device that guides movement direction of fluid entered into internal space of housing part from inlet part toward partition part by configuring second wing part formed inclined downward located above inlet part, and second extension part extended downward from the other end of second wing part.

Yet another object of the present disclosure is to provide collection device that prevents spark generated from scrubber or other from spreading to other place by configuring treatment fluid supply part formed inclined downward along second wing part, allowing treatment fluid to fall into internal space, thereby making all fluid introduced into collection device pass through fluid film.

Yet another object of the present disclosure is to provide collection device that blocks problem that may lead to large fire as flame moves along pipe when explosion of scrubber or other occurs.

Yet another object of the present disclosure is to provide collection device that neutralizes human harmful gases such as ammonia (NH3), silane (SiH4) contained in fluid discharged from scrubber or other, and allows fine particles such as fume contained in fluid to be removed.

Yet another object of the present disclosure is to provide collection device that blocks spread of fire by providing treatment fluid inside collection device installed on pipe connecting scrubber and exhaust duct, so that pipe made of PVC material for corrosion prevention, which is vulnerable to fire, does not become medium for fire spread.

Yet another object of the present disclosure is to provide collection device that blocks fire spread through fluid film and allows corrosion-inducing liquid component contained in fluid treated from scrubber or other to be separated and discharged by configuring treatment fluid supply part penetrating from outside to inside of collection part and dropping treatment fluid in gravity direction at specific position of internal space.

Yet another object of the present disclosure is to provide collection device that allows separated cleaning by configuring treatment fluid supply part to be formed to penetrate housing part and detachably coupled from housing part.

Yet another object of the present disclosure is to provide collection device that allows all target fluid entered into internal space through inlet part to pass through treatment fluid film by forming multiple penetration holes of treatment fluid supply part aligned in rows and columns on bottom surface of storage part, with penetration holes between adjacent rows arranged in staggered manner.

Yet another object of the present disclosure is to provide collection device that allows treatment fluid contained in storage part to fall vertically along gravity direction without moving attaching to lower surface of storage part by surface tension or other even if storage part is positioned inclined, by configuring center axis direction of penetration hole to be parallel to gravity direction.

Yet another object of the present disclosure is to provide collection device that allows fluid to be introduced into internal space of housing part and allows condensed corrosion-inducing liquid component to gather in one place along inclined surface of housing part, by configuring inclined surface at lower part of housing part and making inlet part formed vertically from lower to upper direction penetrating inclined surface to communicate with internal space.

Yet another object of the present disclosure is to provide collection device that minimizes space required for installation when installing collection device between scrubber and exhaust duct by configuring vertical type collection device.

Yet another object of the present disclosure is to provide collection device that minimizes space required for installation of collection device and further increases space efficiency by making inlet part penetrate from lower to upper direction of housing part forming internal space to communicate with internal space.

Yet another object of the present disclosure is to provide collection device that effectively prevents corrosion of pipe by minimizing pressure drop of fluid by preventing bent part from occurring when connecting pipe to collection part.

Yet another object of the present disclosure is to provide collection device that dramatically reduces amount of material used, simplifies pipe construction, and facilitates maintenance after installation by allowing length of inlet part to be shortened without bent part.

Yet another object of the present disclosure is to provide collection device that actively forms vortex of fluid at front end of outlet part by additional space by configuring additional part forming additional space in internal space of housing part.

Yet another object of the present disclosure is to provide collection device that further increases collection efficiency of specific substance by forming parallel to outlet part on one side of collection part where outlet part is formed to generate vortex of fluid in internal space before fluid escapes through outlet part.

Yet another object of the present disclosure is to provide collection device that allows vortex to occur by additional space when collection device is operating by closing opened one side of body part by cap part, and allows inspection or easy cleaning of inside of collection device by separating cap part to open one side of body part when collection device is not operating, by configuring tubular body part with one side and other side opened while forming additional space communicating with internal space, and cap part detachably coupled to body part to open and close one side of body part opened.

Yet another object of the present disclosure is to provide collection device that allows cap part to be easily fixed to or separated from body part as needed, by configuring fixing part that fixes cap part to body part.

### Technical Solution

The present disclosure may be implemented by one or more embodiments having some or all of the following configurations.

According to one embodiment of the present disclosure, the present disclosure comprises a collection part forming an internal space and collecting specific component from target fluid entering into the internal space, an inlet part connected to the collection part and introducing the target fluid into the internal space, a treatment fluid supply part connected to the collection part and supplying treatment fluid into the internal space for collecting the specific component from the target fluid, an outlet part connected to the collection part and discharging the treated target fluid from the internal space to outside, and a discharge part connected to the collection part discharging fluid containing the specific component collected from the internal space to outside, wherein the collection part comprises a housing part forming the internal space, and a partition part dividing the internal space to generate fluid vortex for increasing collection efficiency.

According to another embodiment of present disclosure, the partition part divides one flow path of the internal space into multiple flow paths with different flow path widths and generates fluid vortex by velocity difference of fluid between divided flow paths.

According to yet another embodiment of present disclosure, the partition part is formed parallel to streamline direction rising toward the outlet part.

According to yet another embodiment of present disclosure, the partition part is formed at position spaced apart by certain distance from an inner circumferential surface of a side surface of the housing part, and forms the flow path width formed with the inner circumferential surface of the side surface of the housing part relatively narrow among flow paths divided by partition part, to cause fastest flow velocity in flow path formed by the inner circumferential surface of the side surface of the housing part and the partition part.

According to yet another embodiment of present disclosure, the collection part comprises a first wing part formed in a shape that restricts flow of fluid rising according to guidance of the partition part by positioning above the partition part.

According to yet another embodiment of present disclosure, the first wing part has one end coupled to the inner circumferential surface of the side surface of housing part and other end forming free end, and is formed inclined downward.

According to yet another embodiment of present disclosure, the collection part further comprises a first extension part extended downward from the other end of the first wing part forming a free end.

According to yet another embodiment of present disclosure, the collection part comprises a second wing part formed in a shape that restricts flow of fluid rising from the inlet part by positioning above the inlet part, wherein the second wing part has one end coupled to the inner circumferential surface of the side surface of housing part and other end forming free end, and is formed inclined downward.

According to yet another embodiment of present disclosure, the collection part comprises a second extension part extended downward from the other end of the second wing part forming free end.

According to yet another embodiment of present disclosure, the treatment fluid supply part is formed inclined downward along the second wing part, and comprises a storage part forming accommodation space where the treatment fluid is stored, and a penetration hole which is a hole penetratingly formed in the storage part so that the treatment fluid stored in the accommodation space falls into the internal space.

According to yet another embodiment of present disclosure, the present disclosure comprises a collection part forming an internal space and collecting a specific component from target fluid entering the internal space, an inlet part connected to the collection part and introducing the target fluid into the internal space, a treatment fluid supply part connected to the collection part and supplying treatment fluid into the internal space for collecting the specific component from the target fluid, an outlet part connected to the collection part and discharging the treated target fluid from the internal space to outside; and a discharge part connected to the collection part and discharging fluid containing the collected specific component from the internal space to outside, wherein the collection part comprises a housing part forming the internal space and an additional part forming additional space in the internal space to generate fluid vortex for increasing collection efficiency.

According to yet another embodiment of present disclosure, the additional part is formed parallel to the outlet part on one surface of the collection part where the outlet part is formed, generating vortex of fluid in internal space before fluid escapes through the outlet part.

According to yet another embodiment of present disclosure, the additional part comprises a body part forming additional space communicating with the internal space and having tubular shape with one side and other side opened, and a cap part detachably coupled to the body part to open and close the one side of the body part opened.

According to yet another embodiment of present disclosure, the additional part comprises a fixing part that fixes the cap part to the body part.

According to yet another embodiment of present disclosure, the fixing part comprises a first fixing body formed in shape that grasps the body part and comprises a first fixing hole penetrating from one side to other side, a second fixing body formed in shape that grasps the cap part and comprises a second fixing hole penetrating from one side to other side, and a fastening means being fastened to the first fixing hole and the second fixing hole to couple the first fixing body and the second fixing body.

### Advantageous Effects

The present disclosure may achieve the follow effects from the embodiment and configurations described below, as well as combinations and relationships of use thereof.

According to the present disclosure, the present disclosure provides collection device that maximizes collection efficiency of specific substance to be collected by promoting generation of vortex in internal space of housing part where fluid flows.

According to the present disclosure, the present disclosure provides collection device that promotes generation of vortex by causing velocity difference of fluid by configuring partition part dividing internal space of housing part.

According to the present disclosure, the present disclosure provides collection device that divides one flow path into multiple flow paths with different flow path widths through partition part, causing vortex to occur due to flow velocity difference between flow paths.

According to the present disclosure, the present disclosure provides collection device that generates vortex by partition part, increasing collection efficiency while allowing substance to be discharged smoothly to outside of collection part through discharge part.

According to the present disclosure, the present disclosure provides collection device that forms clockwise vortex from an inner circumferential surface of the side surface of housing part toward center direction of housing part by forming partition part parallel to streamline direction rising toward outlet part from position spaced apart by certain distance from inner circumferential surface of the side surface of housing part, and forming flow path width formed by the inner circumferential surface of the side surface of housing part and partition part relatively narrow to cause fastest flow velocity in corresponding flow path.

According to the present disclosure, the present disclosure provides collection device that forms vortex as fluid rapidly rising by partition part meets a first wing part by configuring the first wing part formed inclined downward on upper side of partition part.

According to the present disclosure, the present disclosure provides collection device that maximizes vortex phenomenon caused by fluid with increased flow velocity due to partition part by configuring first extension part extended downward from the other end of first wing part.

According to the present disclosure, the present disclosure provides collection device that guides movement direction of fluid entered into internal space of housing part from inlet part toward partition part by configuring second wing part formed inclined downward located above inlet part, and configuring second extension part extended downward from the other end of second wing part.

According to the present disclosure, the present disclosure provides collection device that prevents spark generated from scrubber and so forth from spreading to other place by configuring treatment fluid supply part formed inclined downward along second wing part, allowing treatment fluid to fall into internal space, thereby making all fluid introduced into collection device pass through fluid film.

According to the present disclosure, the present disclosure provides collection device that blocks problem of large-scale fire that can occur when flame moves along pipe when explosion of scrubber and so forth occurs.

According to the present disclosure, the present disclosure provides collection device that neutralizes human harmful gases such as ammonia (NH3), silane (SiH4) contained in fluid discharged from scrubber and so forth, and allows fine particles such as fume contained in fluid to be removed.

According to the present disclosure, the present disclosure provides collection device that blocks spread of fire by providing treatment fluid inside collection device installed on pipe connecting scrubber and exhaust duct, so that pipe made of PVC material for corrosion prevention, which is vulnerable to fire, does not become medium for fire spread.

According to the present disclosure, the present disclosure provides collection device that blocks fire spread through fluid film while allowing corrosion-inducing liquid component and so forth contained in fluid treated from scrubber and so forth to be separated and discharged, by configuring treatment fluid supply part penetrating from outside to inside of collection part and dropping treatment fluid in gravity direction at specific position of internal space.

According to the present disclosure, the present disclosure provides collection device that allows separation and cleaning by configuring treatment fluid supply part to be formed penetrating housing part and detachably coupled from housing part.

According to the present disclosure, the present disclosure provides collection device that allows all target fluid entered into internal space through inlet part to pass through treatment fluid film by forming multiple penetration holes of treatment fluid supply part aligned in rows and columns on bottom surface of storage part, with penetration holes between adjacent rows arranged in staggered manner.

According to the present disclosure, the present disclosure provides collection device that allows treatment fluid contained in storage part to fall vertically along gravity direction without moving by surface tension or other even if storage part is positioned inclined, by configuring center axis direction of penetration hole to be parallel to gravity direction.

According to the present disclosure, the present disclosure provides collection device that allows fluid to be introduced into internal space of housing part and allows condensed corrosion inducing liquid component to gather in one place along inclined surface of housing part, by configuring inclined surface at lower part of housing part and making inlet part formed vertically from lower to upper direction penetrate inclined surface to communicate with internal space.

According to the present disclosure, the present disclosure provides collection device that minimizes space required for installation when installing collection device between scrubber and exhaust duct by configuring vertical type collection device.

According to the present disclosure, the present disclosure provides collection device that minimizes space required for installation of collection device and further increases space efficiency by making inlet part penetrate from lower to upper direction of housing part forming internal space to communicate with internal space.

According to the present disclosure, the present disclosure provides collection device that effectively prevents corrosion of pipe by minimizing pressure drop of fluid by preventing bent part from occurring when connecting pipe to collection part.

According to the present disclosure, the present disclosure provides collection device that dramatically reduces amount of materials used, simplifies pipe work, and facilitates maintenance after installation by allowing length of inlet part to be shortened without bent part.

According to the present disclosure, the present disclosure provides collection device that actively forms vortex of fluid at front end of outlet part by additional space by configuring additional part forming additional space in internal space of housing part.

According to the present disclosure, the present disclosure provides collection device that further increases collection efficiency of specific substance by generating vortex of fluid in internal space before fluid escapes through outlet part, formed parallel to outlet part on one side of collection part where outlet part is formed.

According to the present disclosure, the present disclosure provides collection device that allows vortex to occur by additional space when collection device is operating by closing opened one side of body part by cap part, and allows inspection or easy cleaning of inside of collection device by separating cap part and opening one side of body part when collection device is not operating, by configuring tubular body part with one side and other side opened forming additional space communicating with internal space, and cap part detachably coupled to body part to open and close one side of body part opened.

According to the present disclosure, the present disclosure provides collection device that allows cap part to be easily fixed to or separated from body part as needed by configuring fixing part that fixes cap part to body part.

### DESCRIPTION OF DRAWINGS

FIG. 1 is a drawing illustrating a conventional liquid collection device.

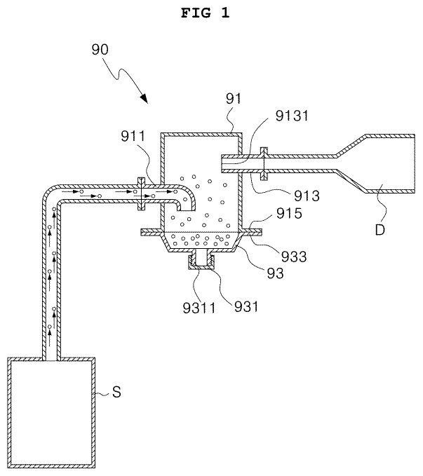

FIG. 2 is a drawing illustrating an installation state of conventional liquid collection device.

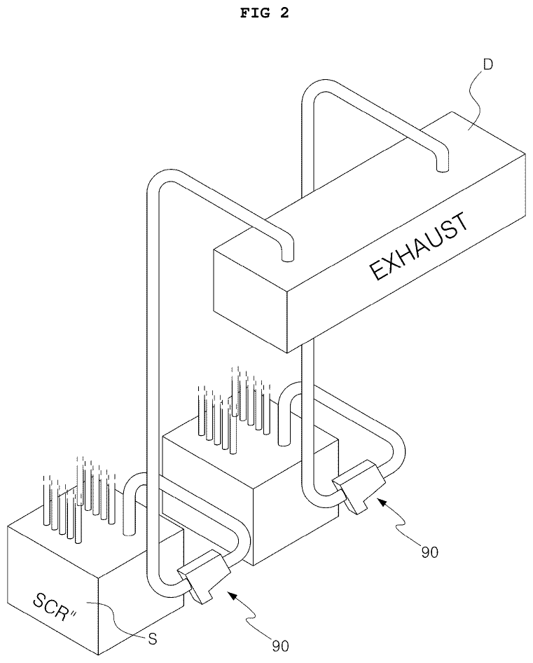

FIG. 3 is a drawing illustrating a collection device according to an embodiment of the present disclosure.

FIG. 4 is a cross-sectional view of A-A′ of FIG. 3.

FIG. 5 is a drawing illustrating usage state of FIG. 3.

FIG. 6 is a drawing illustrating a collection device according to another embodiment of the present disclosure.

FIG. 7 is a partial exploded perspective view of FIG. 6.

FIG. 8 is a cross-sectional view taken along line B-B′ of FIG. 6.

FIG. 9 is a drawing illustrating a use state of FIG. 6.

FIG. 10 is a drawing illustrating an example of an installed state of the collection device of the present disclosure.

### MODE FOR INVENTION

Hereinafter, preferred embodiments of collection device that increases collection efficiency using vortex of fluid according to present disclosure will be described in detail with reference to accompanying drawings. In describing the present disclosure below, detailed description of known functions or configurations will be omitted when it is determined that detailed description may unnecessarily obscure gist of the present disclosure. Unless specifically defined otherwise, all terms used in this specification have same general meanings as understood by those skilled in art to which present disclosure pertains, and if meanings of terms used in this specification conflict, they shall follow definitions used in this specification.

Collection device 1 that increases collection efficiency using vortex of fluid according to present disclosure maximizes collection efficiency of specific substance to be collected by promoting generation of vortex by causing velocity difference of fluid in internal space of housing part where fluid flows, or creating additional space communicating with internal space.

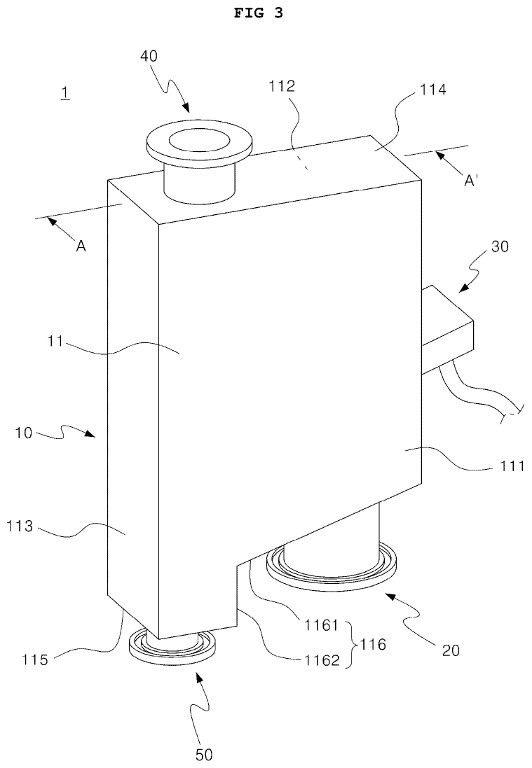

FIG. 3 is a drawing illustrating collection device 1 according to an embodiment of present disclosure, and referring to FIG. 3, collection device 1 of an embodiment of present disclosure comprises collection part 10, inlet part 20, treatment fluid supply part 30, outlet part 40, and discharge part 50.

The collection part 10 refers to configuration that forms internal space and collects specific component from target fluid entered into internal space. One side of the collection part 10 is connected to inlet part 20 to be described later, and other side of the collection part 10 is connected to outlet part 40 to be described later, so that it can collect corrosion-inducing liquid component and so forth and neutralize human harmful gases and so forth from fluid introduced from scrubber and so forth. Fluid introduced through scrubber and so forth may contain strong corrosive substances such as hydrofluoric acid, and collection part 10 prevents corrosion inside pipe by collecting such liquid components so that corrosion-inducing liquid components do not exist in exhausted fluid, and functions to neutralize harmful substances such as ammonia (NH₃), silane (SiH₃) and so forth.

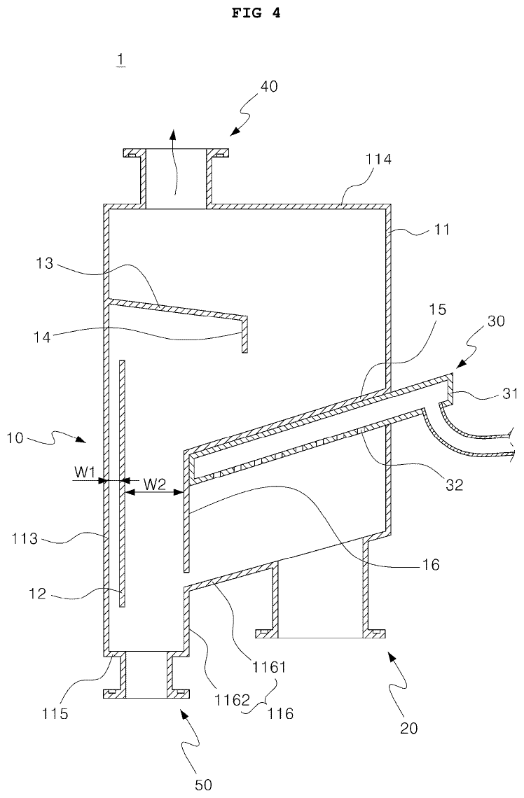

FIG. 4 is a cross-sectional view of A-A′ of FIG. 3, and referring to FIG. 4, the collection part 10 comprises housing part 11, partition part 12, first wing part 13, first extension part 14, second wing part 15, and second extension part 16.

The housing part 11 forms the internal space and overall exterior shape of collection device 1. Referring to FIG. 3, the housing part 11 may have shape of rectangular box with lower part partially removed to form inclined surface. Preferably, inlet part 20 to be described later is coupled to lower part of the housing part 11, and outlet part 40 to be described later is coupled to upper part of the housing part 11, so that fluid introduced through inlet part 20 passes through internal space of the housing part 11 and is discharged through outlet part 40 to be described later. Corrosion-inducing liquid component, human harmful gases and so forth are removed inside the housing part 11, so fluid introduced from inlet part 20 contains corrosion-inducing liquid component, human harmful gases and so forth, but fluid discharged through outlet part 40 does not contain corrosion-inducing liquid component, human harmful gases and so forth.

Referring to FIG. 3, the housing part 11 can be divided into front surface 111, rear surface 112, side surface 113, upper surface 114, lower surface 115, and inclined surface 116.

The front surface 111 refers to vertical surface located at front side of the housing part 11, indicated in FIG. 3.

The rear surface 112 refers to surface located opposite to the front surface 111, indicating vertical surface located at rear side of the housing part 11.

The side surface 113 refers to surface connecting the front surface 111 and the rear surface 112, indicating vertical surfaces located at left and right sides of the housing part 11.

The upper surface 114 refers to horizontal surface located at upper side of the housing part 11, referring to part where outlet part 40 to be described later is coupled.

The lower surface 115 is a surface located at lower side of the housing part 11, and is connected to inclined surface 116 to be described later, and as shown in FIG. 3, discharge part 50 to be described later is coupled to the lower surface 115 so that corrosion-inducing liquid component, treatment fluid and so forth gathered on the lower surface 115 can be discharged to outside of the housing part 11. In FIG. 3 and FIG. 4, the lower surface 115 is shown to form horizontal surface, but to facilitate fluid gathering on the lower surface 115 and discharging through discharge part 50, inclined surface can be formed with area around discharge part 50 elevated so that fluid naturally flows toward discharge part 50.

The inclined surface 116 is a part connected inclinedly to the lower surface 115, and by configuring inclined surface 116 at lower part of the housing part 11 and making inlet part 20 to be described later formed vertically from lower to upper direction, penetrating inclined surface 116 to communicate with internal space of the housing part 11, fluid is introduced into internal space of the housing part 11, and condensed liquid component can gather on the lower surface 115 along inclined surface 116 of the housing part 11. For this, inclined surface 116 can comprise first inclined surface 1161 and second inclined surface 1162 as shown in FIG. 3 and FIG. 4.

The first inclined surface 1161 forms a certain angle and is a part with one end connected to the side surface 113, and preferably refers to surface through which inlet part 20 to be described later penetrates. As shown in FIG. 3 and FIG. 4, inclination angle of the first inclined surface 1161 may be smaller than inclination angle of second inclined surface 1162 to be described later, or alternatively, inclination angle of the first inclined surface 1161 may be configured to be same as or larger than inclination angle of second inclined surface 1162.

The second inclined surface 1162 forms a certain angle and refers to part with one end connected to other side of the first inclined surface 1161 and the other end connected to the lower surface 115. According to FIG. 3 and FIG. 4, the second inclined surface 1162 is expressed as forming angle of 90 degrees, but it is not necessarily limited to this and can have various angles as long as it can guide fluid toward the lower surface 115.

The partition part 12 is a configuration that divides the internal space to cause vortex of fluid that increases collection efficiency, and is characterized by dividing one flow path of the internal space into multiple flow paths with different flow path widths to cause vortex of fluid by velocity difference between divided flow paths. Preferably, the partition part 12 can be configured to have plate-shaped form formed parallel to streamline direction rising toward outlet part 40 to be described later, as shown in FIG. 4. One side of the plate-shaped partition part 12 can be coupled to front surface 111 of the housing part 11, and other side of the partition part 12 can be coupled to rear surface 112 of the housing part 11.

More preferably, the partition part 12 is formed at position spaced apart by certain distance W1 from inner circumferential surface of the side surface 113 of the housing part 11, and forms flow path width W1 formed with inner circumferential surface of the side surface 113 of the housing part 11 relatively narrow (W1<W2) among flow paths divided by the partition part 12, to cause fastest flow velocity in flow path formed by circumferential surface of the side surface 113 of the housing part 11 and the partition part 12. Accordingly, clockwise vortex can be formed from inner circumferential surface of the side surface of the housing part 11 toward center direction of housing part, thereby increasing collection efficiency of specific substance while allowing substance to be discharged smoothly to outside of the collection part 10 through discharge part 50 to be described later.

The first wing part 13 refers to configuration formed in shape that restricts flow of fluid rising according to guidance of the partition part 12 by positioning above the partition part 12. Preferably, the first wing part 13 can be plate-shaped member formed inclined downward with one end coupled to inner circumferential surface of the side surface of the housing part 11 and the other end forming free end. By configuring the first wing part 13 formed inclined downward on upper side of the partition part 12, fluid rapidly rising by the partition part 12 forms vortex as it meets the first wing part 13.

The first extension part 14 is configuration extended downward from the other end of the first wing part 13 forming free end, and as shown in FIG. 4, by configuring the first extension part 14, vortex phenomenon caused by fluid with increased flow velocity due to the partition part 12 can be maximized. Preferably, the first extension part 14 can be formed extended vertically from the other end of the first wing part 13 as shown in FIG. 4.

The second wing part 15 is configuration formed in shape that restricts flow of fluid rising from inlet part 20 to be described later by positioning above inlet part 20, and one end of the second wing part 15 is coupled to inner circumferential surface of the side surface 114 of the housing part 11, the other end forms a free end, and can be formed inclined downward. Through the second wing part 15, movement direction of fluid entered into internal space of the housing part 11 from inlet part 20 to be described later is guided toward the partition part 12.

The second extension part 16 refers to configuration extended downward from the other end of the second wing part 15 forming free end. It is preferable that end of the second extension part 16 is configured not to meet inclined surface 116 of the housing part 11 so that fluid can move into a space between the second extension part 16 and inclined surface 116 of the housing part 11. Preferably, the second extension part 16 can be formed extended vertically downward from the other end of the second wing part 15 as shown in FIG. 4.

The inlet part 20 refers to configuration connected to the collection part 10 and introducing the target fluid into the internal space. Preferably, fluid treated from scrubber and so forth can enter internal space of the housing part 11 through the inlet part 20. The shape of the inlet part 20 is not limited to any specific shape, but as shown in FIG. 3, it can be configured in cylindrical shape with upper and lower surfaces opened. The inlet part 20 is formed vertically extended from lower to upper direction, and penetrates inclined surface 116 of the housing part 11 to communicate with internal space of the housing part 11. The inlet part 20 of collection device 1 of the present disclosure is configured as vertical pipe standing upright without bending, thereby preventing problem of load when fluid discharged through scrubber and so forth passes through the inlet part 20, and problem of corrosion due to large pressure drop. Also, by being able to shorten length of inlet part 20 without bent part, it dramatically reduces amount of materials used, simplifies pipe work, and facilitates maintenance after installation.

The treatment fluid supply part 30 refers to configuration connected to the collection part 10 and supplying treatment fluid for collecting the specific component from the target fluid into the internal space. Preferably, the treatment fluid supply part 30 is formed to penetrate side surface 113 of the housing part 11 and detachably coupled to the housing part 11 for easy separation and cleaning, and can be seen as a configuration adhering to lower surface of the second wing part 15. Fluid film or fluid curtain that blocks fire spread can be formed by the treatment fluid supply part 30, and the treatment fluid is not limited to any specific fluid, but preferably, it can be composed of water (H2O), and therefore, fluid film formed by the treatment fluid supply part 30 can be water film. Also, the treatment fluid can be composed of neutralizing agent that neutralizes harmful gases and so forth. Used treatment fluid can be continuously used through recycling process.

The treatment fluid supply part 30, as shown in FIG. 4, is configured to be in close contact with lower surface of the second wing part 15, so that even with configuration of the treatment fluid supply part 30, internal space of the housing part 11 is not significantly reduced, allowing sufficient liquid collection without increasing size of collection device 1.

The treatment fluid supply part 30 is formed inclined downward along the second wing part 15. By allowing treatment fluid to fall into internal space through the treatment fluid supply part 30, all fluid introduced into the collection device 1 passes through fluid film, preventing spark generated from scrubber and so forth from spreading to other places. Also, when explosion and so forth of scrubber occurs, it fundamentally blocks problem of large-scale fire that can occur when flame moves along pipe. Moreover, it neutralizes human harmful gases such as ammonia (NH3), silane (SiH3) and so forth contained in fluid discharged from scrubber and so forth, and allows fine particles such as fume contained in fluid to be removed.

Referring to FIG. 4, the treatment fluid supply part 30 comprises storage part 31 and penetration hole 32.

The storage part 31 forms accommodation space where the treatment fluid is stored, and can be detachably coupled to the housing part 11. Preferably, the storage part 31 can be formed in empty box shape as shown in FIG. 4. The storage part 31 penetrates side surface 113 of the housing part 11, and is formed inclined downward to induce smooth flow of treatment fluid.

The penetration hole 32 refers to a hole penetratingly formed in the storage part 31 so that the treatment fluid stored in the accommodation space falls into the internal space. Preferably, the penetration hole 32 can be formed only on part of lower surface of the storage part 31 inserted into internal space of the housing part 11 to prevent leakage of treatment fluid outside of the housing part 11. Preferably, multiple penetration holes 32 of the treatment fluid supply part 30 are formed aligned in rows and columns on lower surface of the storage part 31, with penetration holes 32 between adjacent rows arranged in staggered manner, so that all target fluid entered into internal space of the housing part 11 through the inlet part 20 can pass through treatment fluid film. And, by configuring center axis direction of the penetration hole 32 to be parallel to gravity direction, even if the storage part 31 is positioned inclined, treatment fluid contained in the storage part 31 can fall vertically along gravity direction without moving by surface tension and so forth on lower surface of the storage part 31.

The outlet part 40 is a configuration connected to the collection part 10 and discharging target fluid treated in the internal space to outside of the internal space, discharging fluid from which corrosion-inducing liquid component, human harmful gases and so forth have been removed in the collection part 10. The shape of the outlet part 40 is not limited to any specific shape, but preferably, it can be configured in cylindrical shape with upper and lower surfaces open. As mentioned earlier, the inlet part 20 was configured to penetrate inclined surface 116 of the housing part 11, but the outlet part 40 is preferably viewed as being formed vertically extended upward from upper surface 114 of the housing part 11 communicating with internal space of the housing part 11. The outlet part 40 of collection device 1 of present disclosure can also be configured in form of vertical pipe standing upright without bending, so that even when installing collection device 1 between scrubber and exhaust duct, it does not require wide installation space, and problems of load and pressure drop phenomenon are prevented as pipes are connected vertically. Also, it prevents foreign substances from sticking to inner wall of pipe to form scale, can block corrosion inside pipe by corrosion-inducing liquid component, and can neutralize human harmful gases and so forth.

The discharge part 50 is a configuration connected to the collection part 10 that discharges fluid containing the collected specific component to outside of the internal space. Specifically, the discharge part 50 is coupled to the lower surface 115 of the housing part 11 to drain collected corrosion-inducing liquid components and treatment fluid to the outside. For this purpose, the discharge part 50 can be configured in a tubular shape with open top and bottom surfaces, preferably in a cylindrical shape. When corrosion-inducing liquid components condensed by colliding with the first wing part 13 and other parts fall due to gravity, they gather on the lower surface 115 of the housing part 11. The discharge part 50 is configured on this lower surface 115, allowing the collected specific components to be discharged to the outside of the housing part 11. Additionally, the treatment fluid continuously supplied to the internal space of the housing part 11 to form a fluid film for preventing fire spread falls due to gravity. This fallen treatment fluid gathers in the discharge part 50 and is discharged outside the housing part 11, where it can be reused after going through processes such as filtering.

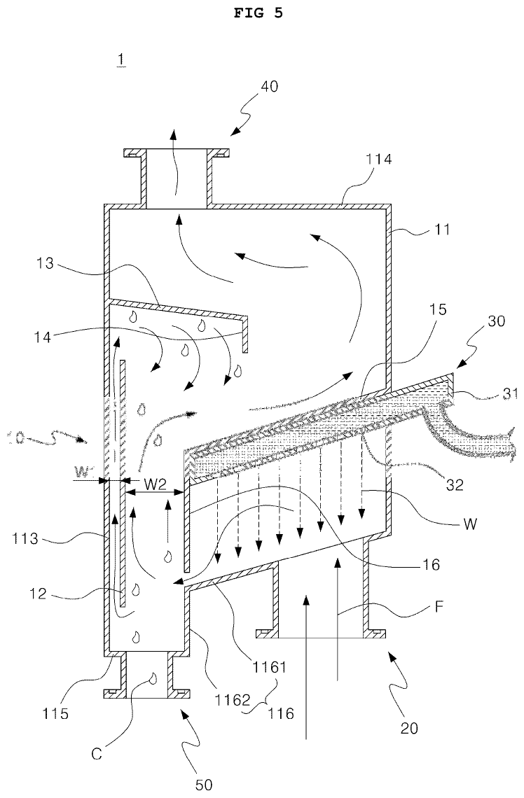

FIG. 5 illustrates the use state of FIG. 3. Referring to FIG. 5, the fluid F entering the internal space of the housing part 11 through the inlet part 20 meets the treatment fluid W falling from the treatment fluid supply part 30. This not only prevents fire spread but also neutralizes human harmful gases such as ammonia (NH3), silane (SiH3) and so forth contained in the fluid, and removes fine particles such as fume contained in the fluid.

Subsequently, the fluid F is guided by the second wing part 15 and second extension part 16 to move downward. The flow path that the fluid F encounters after passing through the space between the end of the second extension part 16 and the inclined surface 116 of the housing part 11 can be divided into two flow paths by the partition part 12, as shown in FIG. 5. The partition part 12 is offset towards the side surface 113 of the housing part 11, making the width W1 of the flow path closer to the side surface 113 narrower than the width W2 of the other flow path (W1<W2), resulting in faster fluid F velocity in the flow path with width W1.

In other words, velocity of fluid F passing through flow path with width WI becomes faster compared to velocity of fluid F passing through flow path with width W2, and first wing part 13 inclined downward is positioned above the partition part 12, causing vortex as shown in FIG. 5 by fluid F that passed through flow path with width W1.

When creating negative pressure on the outlet part 40 side to suck in fluid F, a problem may occur where collected liquid components and so forth C cannot escape to outside of the housing part 11 through the discharge part 50 despite needing to be discharged toward the discharge part 50 side, as pressure difference increases due to the negative pressure.

To solve this problem, as shown in FIG. 5, present disclosure forms clockwise vortex by fluid F that passed through flow path with width W1, generating flow opposite to flow of fluid F rising through flow path with width W2, thereby enabling discharge of component C through the discharge part 50 while increasing collection efficiency.

Through such process, fluid F with specific component C removed moves outside the housing part 11 through outlet part 40 formed on upper surface 114 of the housing part 11.

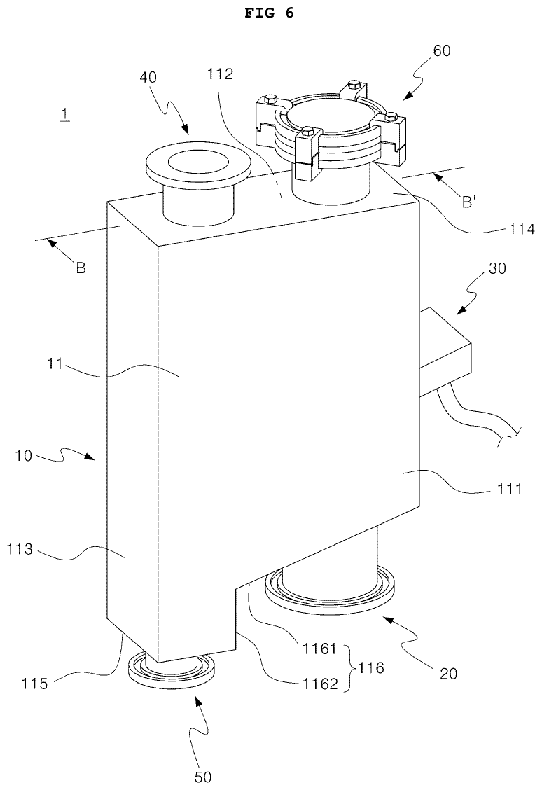

FIG. 6 is a drawing illustrating collection device according to another embodiment of present disclosure, and referring to FIG. 6, embodiment of FIG. 6 is configured with an additional part 60 unlike previously described embodiment, and hereinafter, newly added additional part 60 will be described.

The additional part 60 is a configuration that forms additional space in the internal space to cause vortex of fluid that increases collection efficiency, and is characterized by being formed parallel to the outlet part 40 on upper surface 114 of housing part 11 of the collection part 10 where the outlet part 40 is formed, generating vortex of fluid in internal space before fluid escapes through the outlet part 40. By additional space formed by the additional part 60, vortex of fluid can be actively formed at front end of the outlet part 40, thereby further increasing collection efficiency of specific substance.

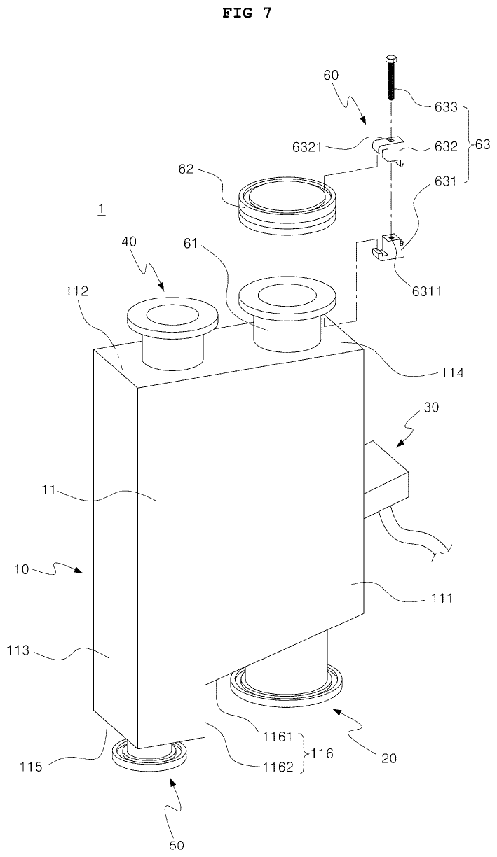

FIG. 7 is a partial exploded perspective view of FIG. 6. Referring to FIG. 7, the additional part 60 comprises body part 61, cap part 62, and fixing part 63.

The body part 61 refers to tubular configuration with one side and other side opened forming additional space communicating with the internal space. FIG. 7 shows the body part 61 in cylindrical shape, but the body part 61 is not necessarily limited to this shape and can be configured in angular pipe shape and so forth. This body part 61 can have flange formed to facilitate easy coupling with cap part 62 to be described later.

The cap part 62 refers to configuration detachably coupled to the body part 61 to open and close one side of the body part 61 opened. For this, the cap part 62 can be configured in shape with lower surface opened while forming empty space inside. When the collection device 1 is operating, opened one side of the body part 61 is closed by the cap part 62 to cause vortex by additional space, and when the collection device 1 is not operating, the cap part 62 is separated to open one side of the body part 61, allowing inspection or easy cleaning of inside of the collection device 1.

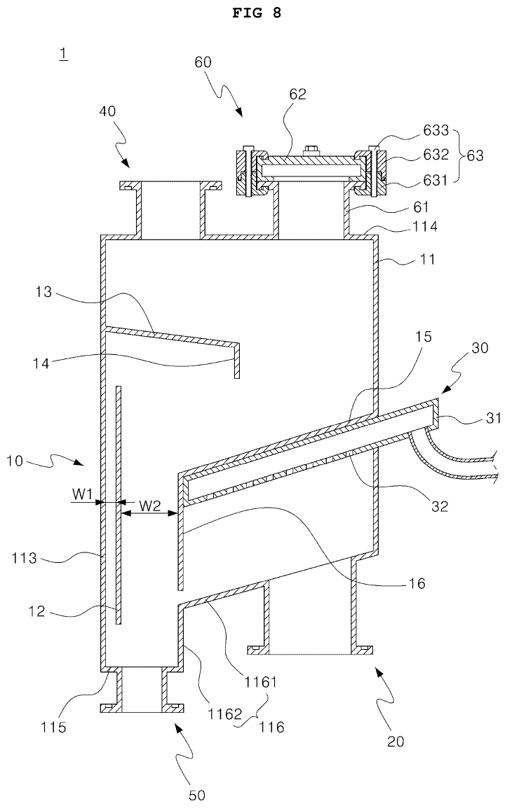

The fixing part 63 is a configuration that fixes the cap part 62 to the body part 61, allowing easy fixing or separation of the cap part 62 to the body part 61 as needed by configuring the fixing part 63. The shape of the fixing part 63 is not limited to any specific shape, and can be configured in shape as shown in FIG. 7 as an example. FIG. 7 is a partial exploded perspective view of FIG. 6, and FIG. 8 is a cross-sectional view of B-B′ of FIG. 6. Referring to FIG. 7 and FIG. 8, the fixing part 63 comprises first fixing body 631, second fixing body 632, and fastening means 633.

The first fixing body 631 refers to configuration formed in shape that grasps the body part 61 and comprising first fixing hole 6311 penetrating from one side to other side. Female thread complementary to male thread formed on outer circumferential surface of fastening means 633 to be described later can be formed on inner circumferential surface of the first fixing hole 6311.

The second fixing body 632 refers to configuration formed in shape that grasps the cap part 62 and comprising second fixing hole 6321 penetrating from one side to other side. Female thread complementary to male thread formed on outer circumferential surface of fastening means 633 to be described later can also be formed on inner circumferential surface of the second fixing hole 6321.

The fastening means 633 is configuration that fastens to the first fixing hole 6311 and the second fixing hole 6321 to couple the first fixing body 631 and the second fixing body 632, and preferably, the fastening means 633 can be bolt with thread formed on outer circumferential surface.

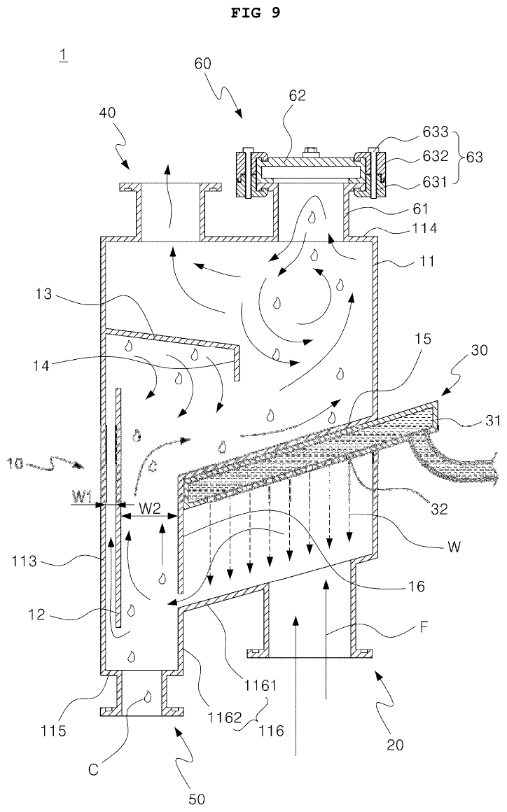

FIG. 9 is a drawing illustrating usage state of FIG. 6, and hereinafter, usage state of this embodiment will be described referring to FIG. 9.

Since FIG. 9 is FIG. 5's use state drawing with the additional part 60 additionally formed, vortex phenomenon by the partition part 12 that occurred in FIG. 5 appears as it is. While in FIG. 5, only fluid F vortex by the partition part 12, the first wing part 13 and the first extension part 14 occurred, in FIG. 9, after vortex of FIG. 5 occurs primarily, secondary vortex as shown in FIG. 9 occurs by additional space inside the body part 61 formed by the additional part 60.

In other words, according to embodiment of FIG. 9, fluid F with specific component C removed by primary vortex is not immediately discharged through outlet part 40, but forms secondary vortex due to fluid flow trying to move towards additional space as internal space suddenly expands by additional space appearing during movement process, and in this process, residual specific component C can be removed once more.

In collection device 1 of FIG. 9, the additional part 60 not only functions to generate secondary vortex, but also facilitates maintenance by allowing inspection or cleaning of device interior when collection device 1 is not operating by opening cap part 62 of the additional part 60.

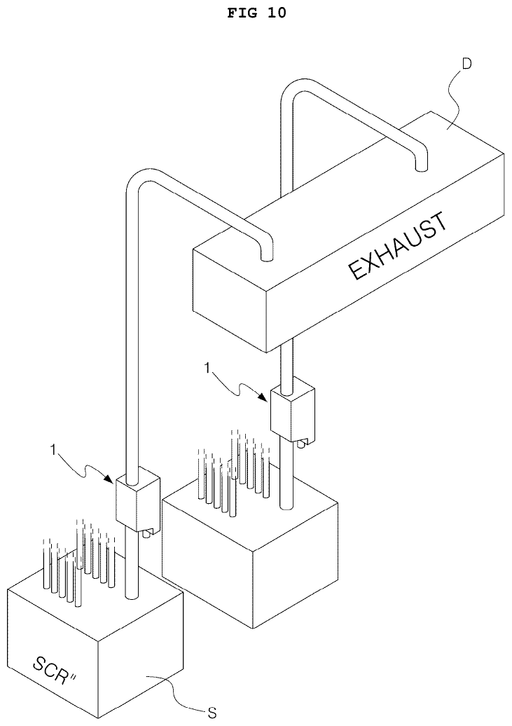

FIG. 10 is a drawing illustrating an example of installed state of collection device 1 of present disclosure, and according to an embodiment of present disclosure, by configuring vertical type collection device 1, space required for installation can be minimized when installing between scrubber S and exhaust duct D.

In FIG. 10, collection device 1 of present disclosure is illustrated installed outside scrubber, but collection device 1 of present disclosure is not necessarily limited to being installed only outside scrubber S, and can also be installed inside scrubber S. In other words, present disclosure can also make it possible to place collection device 1 inside scrubber S so that collection device 1 installed inside scrubber S collects and processes fluid to be discharged by operation of scrubber S before discharging.

Collection device 1 of present disclosure provides internal space to communicate with the inlet part 20 penetrating from lower to upper direction of the housing part 11 forming internal space, thereby minimizing space required for installation of collection device 1 and further increasing space efficiency. By preventing bent parts when connecting pipe to the collection part 10, it becomes possible to provide collection device 1 that effectively prevents corrosion of pipe by minimizing pressure drop of fluid. Also, by being able to shorten length of the inlet part 20 without bent parts, it can provide collection device 1 that dramatically reduces amount of materials used, simplifies pipe work, and facilitates maintenance after installation.

The description provides an exemplary embodiment of the present disclosure, and the present disclosure may be used in other various combination, changes, and environments. That is, the present disclosure may be changed or modified within the scope of the present disclosure described herein, a range equivalent to the description, and/or within the knowledge or technology in the related art. The embodiments show an optimum state for achieving the spirit of the present disclosure, and various modifications required for specific applications and uses of the present disclosure are also possible. Therefore, the detailed description of the present disclosure is not intended to limit the present disclosure in the embodiment. In addition, the claims should be construed as comprising other embodiments.

1. A collection device for increasing collection efficiency using fluid vortex, comprising:
a collection part forming an internal space and collecting specific component from target fluid entering the internal space,
an inlet part connected to the collection part and introducing the target fluid into the internal space,
a treatment fluid supply part connected to the collection part and supplying treatment fluid into the internal space for collecting the specific component from the target fluid,
an outlet part connected to the collection part and discharging treated target fluid from the internal space to outside; and
a discharge part connected to the collection part and discharging fluid containing the specific component collected from the internal space to outside,
wherein the collection part comprises a housing part forming the internal space and a partition part dividing the internal space to generate fluid vortex for increasing collection efficiency.

2. A collection device for increasing collection efficiency using fluid vortex of claim 1,
wherein the partition part divides one flow path of the internal space into multiple flow paths with different flow path widths and generates fluid vortex by velocity difference of fluid between divided flow paths.

3. A collection device for increasing collection efficiency using fluid vortex of claim 2,
wherein the partition part is formed parallel to streamline direction rising toward the outlet part.

4. A collection device for increasing collection efficiency using fluid vortex of claim 3,
wherein the partition part is formed at position spaced apart by certain distance from an inner circumferential surface of a side surface of the housing part, and forms flow path width formed with the inner circumferential surface of the side surface of the housing part relatively narrow among flow paths divided by partition part, to cause fastest flow velocity in flow path formed by the inner circumferential surface of the side surface of the housing part and the partition part.

5. A collection device for increasing collection efficiency using fluid vortex of claim 1,
wherein the collection part comprises a first wing part formed in a shape that restricts flow of fluid rising according to guidance of the partition part by positioning above the partition part.

6. A collection device for increasing collection efficiency using fluid vortex of claim 5,
wherein the first wing part has one end coupled to the inner circumferential surface of the side surface of housing part and the other end forming free end, and is formed inclined downward.

7. A collection device for increasing collection efficiency using fluid vortex of claim 6,
wherein the collection part further comprises a first extension part extended downward from the other end of the first wing part forming free end.

8. A collection device for increasing collection efficiency using fluid vortex of claim 1,
wherein the collection part comprises a second wing part formed in shape that restricts flow of fluid rising from the inlet part by positioning above the inlet part, and
the second wing part has one end coupled to the inner circumferential surface of the side surface of housing part and the other end forming free end, and is formed inclined downward.

9. A collection device for increasing collection efficiency using fluid vortex of claim 8,
wherein the collection part comprises a second extension part extended downward from the other end of the second wing part forming free end.

10. A collection device for increasing collection efficiency using fluid vortex of claim 8,
wherein the treatment fluid supply part is formed inclined downward along the second wing part, and
comprises a storage part forming accommodation space where the treatment fluid is stored, and a penetration hole which is a hole penetratingly formed in the storage part so that the treatment fluid stored in the accommodation space falls into the internal space.

11. A collection device for increasing collection efficiency using fluid vortex, comprising:
a collection part forming an internal space and collecting a specific component from target fluid entering the internal space,
an inlet part connected to the collection part and introducing the target fluid into the internal space,
a treatment fluid supply part connected to the collection part and supplying treatment fluid into the internal space for collecting the specific component from the target fluid,
an outlet part connected to the collection part and discharging the treated target fluid from the internal space to outside; and
a discharge part connected to the collection part and discharging fluid containing the collected specific component from the internal space to outside,
wherein the collection part comprises a housing part forming the internal space and an additional part forming additional space in the internal space to generate fluid vortex for increasing collection efficiency.

12. A collection device for increasing collection efficiency using fluid vortex of claim 11,
wherein the additional part is formed parallel to the outlet part on one surface of the collection part where the outlet part is formed, generating vortex of fluid in internal space before fluid escapes through the outlet part.

13. A collection device for increasing collection efficiency using fluid vortex of claim 11,
wherein the additional part comprises a body part forming additional space communicating with the internal space and having tubular shape with one side and other side opened, and a cap part detachably coupled to the body part to open and close the one side of the body part opened.

14. A collection device for increasing collection efficiency using fluid vortex of claim 13,
wherein the additional part comprises a fixing part that fixes the cap part to the body part.

15. A collection device for increasing collection efficiency using fluid vortex of claim 14,
wherein the fixing part comprises a first fixing body formed in a shape that grasps the body part and comprising a first fixing hole penetrating from one side to other side, a second fixing body formed in a shape that grasps the cap part and comprising a second fixing hole penetrating from one side to other side, and a fastening means that being fastened to the first fixing hole and the second fixing hole to couple the first fixing body and the second fixing body.
